(19) United States
(12) Patent Application Publication
(10) Pub. No.: US 2006/0243962 A1
(43) Pub. Date: Nov. 2, 2006

(54) Quantum dot resonant tunneling device

(76) Inventors: Shiang-Feng Tang, Longtan Township (TW); Cheng-Der Chiang, Taipei City (TW); San-Te Yang, Pingjhen City (TW); Jiunn-Jye Ruo, Longtan Township (TW); Shun-Lung Yen, Keelung City (TW)

Correspondence Address: J.C. Patents, Inc., 4 Venture, Suite 250, Irvine, CA, 92618, US

(21) Appl. No.: 11/282,757

(22) Filed: Nov. 17, 2005

(30) Foreign Application Priority Data
Apr. 28, 2005 (TW) 94113583

(51) Int. Cl. H01L 29/06

(52) U.S. Cl. 257/25

(57) ABSTRACT

A quantum-dot resonant-tunneling device apparatus is provided. The quantum-dot resonant-tunneling device apparatus includes a pair of top-and-down N-type electron injection layers and a pair of quantum-dot layers sandwiched with at least a period of double-barrier. The pair of top-and-down N-type electron injection layers is provided with an adequate positive or negative electric field which leads to electronic resonant-tunneling transportation in the quantum-dot layers mentioned above. In addition, once the electrons are tunneling transported in the device, the device serves as a negative resistance device. The device does not only provide bipolar negative resistance capability and a superior temperature stability within a very wide temperature range, but also operates well under room temperature.

### CROSS-REFERENCE TO RELATED APPLICATION

This application claims the priority benefit of Taiwan application serial no. 94113583, filed on Apr. 28, 2005. All disclosure of the Taiwan application is incorporated herein by reference.

### BACKGROUND OF THE INVENTION

1. Field of the Invention

The present invention relates to an electronic device apparatus, and more particularly, to a resonant-tunneling quantum-dot semiconductor device. In such device, the resonant-tunneling effect occurs in the electron transportation via quantum dots due to the three dimensional energy band confined enhancement. Accordingly, the device serves as a negative resistance device in the macro electrical characteristics, high temperature-stability and can be operated at room temperature.

2. Description of the Related Art

In the conventional electronic devices such as High Electron Mobility Transistor (HEMT) or Metal Oxide Semiconductor Field Effect Transistor (MOSFET), the electrons are horizontally transported, such that the circuit layout area is enlarged, which affects the performance of the entire high-speed chip.

In addition, a high-purity 2D electron gas is required in the HEMT structure, and the gate channel length of the MOSFET must be shortened so as to comply with the high-frequency operation requirement. Accordingly, the diode structure in which the electrons are vertically transported becomes more popular. Since it is a two-terminal device, the fabricating complexity is much lower than that for the three-terminal or four-terminal device.

For the device having the quantum effect, the double barrier confined and periodic superlattice diode becomes a mainstream product in the industry, and it is mainly made of the III-V family compound semiconductor material, especially the GaAs material. The main reason for this is that the fabricating process of GaAs is already mature, and the mobility of the electrons in GaAs is higher than that in the IV family device, such that the entire operating frequency is significantly improved. Especially for the diode structure, the total device capacitance including the depletion capacitance, the diffusion capacitance, and the scattering capacitance can be designed lower than the essence capacitance of the HMET and MOSFET, where most carriers are horizontally transported, thus the frequency bandwidth is also indirectly improved.

Moreover, the requirement of designing an ultra-thin structure layers are grown by applying the current metal-organic vapor phase epitaxy (MOCVD) or molecular beam epitaxy (MBE) technique, thus the bandwidth of the operating frequency in the quantum resonant-tunneling diode with vertical structure can be easily higher as the range of 30˜300 GHz. Recently, since the quantum-dot epitaxial technique had greatly improved, the carriers of the injection layer can be captured by the quantum-dot matrax of the zero dimensional (0D) and discrete energy levels by separating the energy tunneling barriers, and the electrons are transported by resonant tunneling transportation mechanism between the 2D wetting layer and the quantum well. Accordingly, the possibility of the carriers tunneling in the confined band-structure levels is significantly improved, and the resonant-tunneling effect even occurs under room temperature, such that the electronic device has a negative resistance feature.

Accordingly, in order to design the resonant-tunneling diode that has a low biasing-shift and is insensitive to the operating temperature, using the quantum well diode structure with the conventional double barrier confinement alone cannot fulfill its characteristic and specification.

In order to obtain a higher peak-to-valley current ratio and take advantage of the silicon-based IC integration, one experiment had been conducted by N. Evers (GIT) and T. S. Moise (TI) in 1996, sponsored by the Darpa ULTRA and NSF, to form the AlAs/In_{0.53}Ga_{0.47}As/InAs on the InP substrate with the matched silicon crystal lattices. In such experiment, the complicated substrate removal and bonding technique are applied and the silicon nitride is used as a medium layer to bond the silicon substrate. For doing so, the complexity of the device structure design, the epitaxy growth, and the fabricating process techniques must be improved, thus although such method can improve the device performance, it also leads to overall low yield rate.

In 1996, M. Narihiro et al (Tokyo University) first observed that the electron resonant tunneling happens between the InAs quantum-dots of the larger than 20 nm when the temperature is lower than 4.2K. However, the feasibility and the stability of the high temperature operation are not further studied. In 1997, Takaya Nakano et al (Japanese researchers) had done a full study on the quantum-dot double-barrier tunneling diode. It is observed from the investigation that the characteristics of the double-steady state are provided by the charging effect in InAs quantum-dots, and its negative resistance feature is not unobvious. In some cases, the negative resistance only occurs when the temperature is lower than 77K, and the resonant-tunneling effect does not even happen when a positive bias is provided (here the terminal far away from the injection port of the substrate is regarded as the positive terminal).

### SUMMARY OF THE INVENTION

In the conventional technique, the GaAs/AlAs/GaAs/AlAs/GaAs structure is more popular and commonly used in the conventional resonant-tunneling diode (RTD). Wherein, a barrier is formed by AlAs, and a quantum well is formed if a thin layer of GaAs is disposed between the layers, thus several discontinuous energy levels are generated. When the electron energy in the injection layer is equal to a certain energy level in the quantum well, it has the highest possibility of penetrating the barrier layer which results in the maximum peak-current in the device. It can be further explained as follows: When the device is operated under an accumulated bias condition, the carriers are transmitted by tunneling through the barrier layer; once the bias continues to rise up such that the electron energy approaches a lowest energy level of the quantum well, the current approaches to its peak value. If the bias continues to rise up such that the electron energy exceeds the lowest energy level of the quantum well, the possibility of penetrating the barrier layer decreases, and the current also decreases, leading to the formation of a negative resistance region. Since such device has a negative resistance effect and an additionally interfacial capacitor, if an appropriate load is externally connected to the device, the device can be applied on the oscillator, the ultra fast pulse-forming circuit, and the THz radiation detection system, and so on.

In order to offer the characteristics not achieved by the device designed in the conventional technique, a new device is provided by the present invention. The new device has bipolar resonant-tunneling capability, and also can be operated under both the room temperature and a very wide temperature range. The new device also has very good temperature-stability. When it is operated under a very wide temperature range such as 20˜300K with both positive and negative biases, the peak bias drifts are only 0.036 and 0.107 mV/K, respectively. And the current peak-to-valley bias drift is only 0.393 mV/K. In addition, the temperature drift of the current peak-to-valley bias differences in the very wide temperature range under the positive and negative biases are only 0.429 and 0.286 mV/K, respectively. With such characteristics, the device of the present invention is more convenient, more reliable and more flexible to be applied to various oscillator circuits.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic structure diagram of a resonant-tunneling device.

FIG. 2 is a conductance-voltage curve diagram of the device provided by the present invention under a temperature of 20˜300K.

FIGS. 3(a) and 3(b) schematically show the current-voltage electricity characteristic diagrams of the device provided by the present invention when scanned by a voltage of 0˜+1.5V and 0˜−1.5V, respectively.

FIGS. 4(a) and 4(b) schematically show the curve diagrams illustrating the variance of the current peak-to-valley value position to the temperature of the device provided by the present invention under the positive and negative biases, respectively.

FIG. 5 is a schematic diagram showing the voltage relative position differences of the current peak-to-valley values to the temperature drifts of the device provided by the present invention under the positive and negative biases.

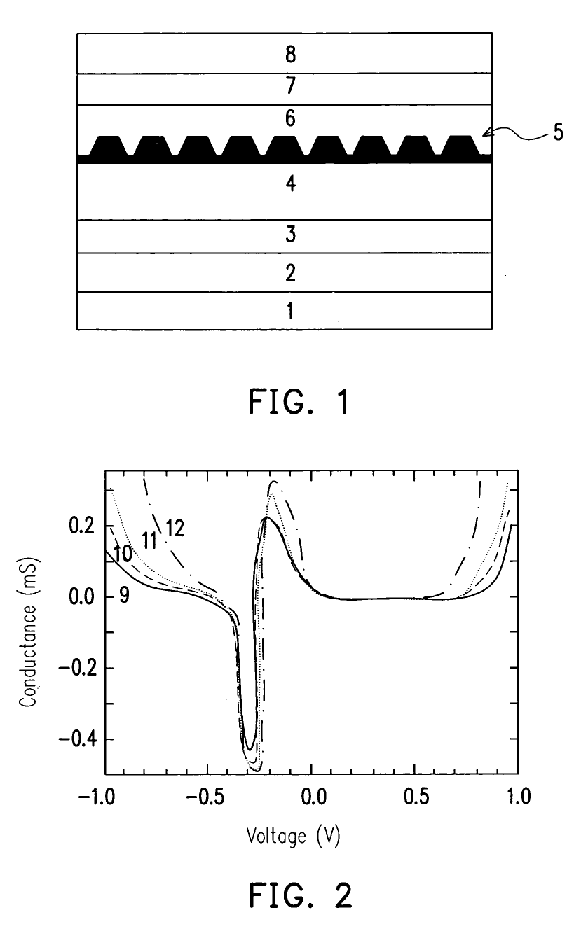

### DESCRIPTION PREFERRED EMBODIMENTS

The molecular beam epitaxy (MBE) or the metal-organic vapor phase epitaxy (MOCVD) technique is used as a preferred process for fabricating the device of the present invention in an epitaxial equipment. The process includes the following steps. First, a GaAs substrate sealed in the nitrogen package is opened and put into the epitaxy machine mentioned above, and the machine temperature is increased to about 580˜630° C., such that the poorly bonded layer and the native oxide layer can be removed from the surface of the substrate. Next, the temperature is fixed on 580˜610° C. to grow and form a buffer layer that is also used as a bottom semiconductor electron injection layer. Then, the growth temperature is reduced to 470˜530° C., so as to form a bottom semiconductor barrier layer defined by the one of periodic double-barriers. Then, the growth temperature is maintained on 470˜530° C., so as to grow a periodic bottom semiconductor spacer layer and a periodic quantum-dot array layer, wherein the average thickness of the quantum-dot layer is about 1.8˜3 mL. Afterwards, under the growth temperatures mentioned above, a periodic top semiconductor spacer layer, a top semiconductor barrier layer defined by another one of periodic double-barrier, and a top semiconductor electron injection layer is sequentially formed thereon. Finally, a structure of the symmetric bipolar quantum-dot resonant-tunneling diode device is formed.

Compared to the structure proposed by the researchers such as T. S. Moise, M. Narihiro, and Takaya Nakano et al, the device structure disclosed in the present invention is advantageous in its simple and symmetric structure design as well as the stability and reliability of the operations under a very wide temperature range.

FIG. 2 is a conductance-voltage curve diagram of the device provided by the present invention under a temperature of 20˜300K. As shown in FIG. 2, there are two negative conductance regions. It is apparent that when a negative bias is applied, the negative conductance in the room-temperature is about −0.45 mS.

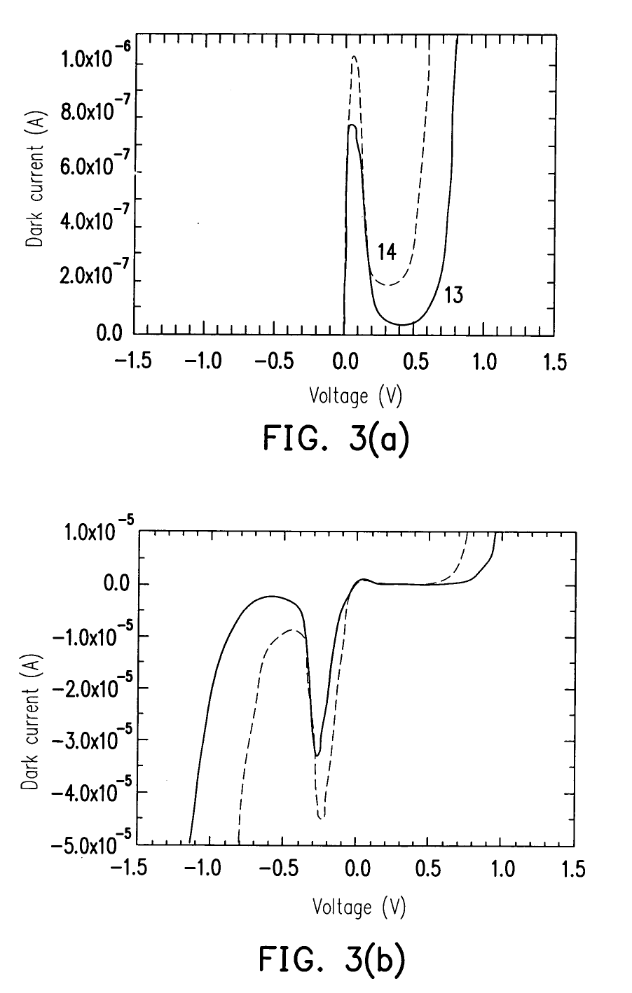

FIGS. 3(a) and 3(b) schematically show the current-voltage characteristic diagrams of the device provided by the present invention when scanned by a voltage of 0˜+1.5V and 0˜−1.5V, respectively. It is known from the diagrams that the variance of the current peak-to-valley range is within ±0.6V. In other words, the device serves as a negative resistance device under the low bias. Accordingly, it can be operated under a lower bias.

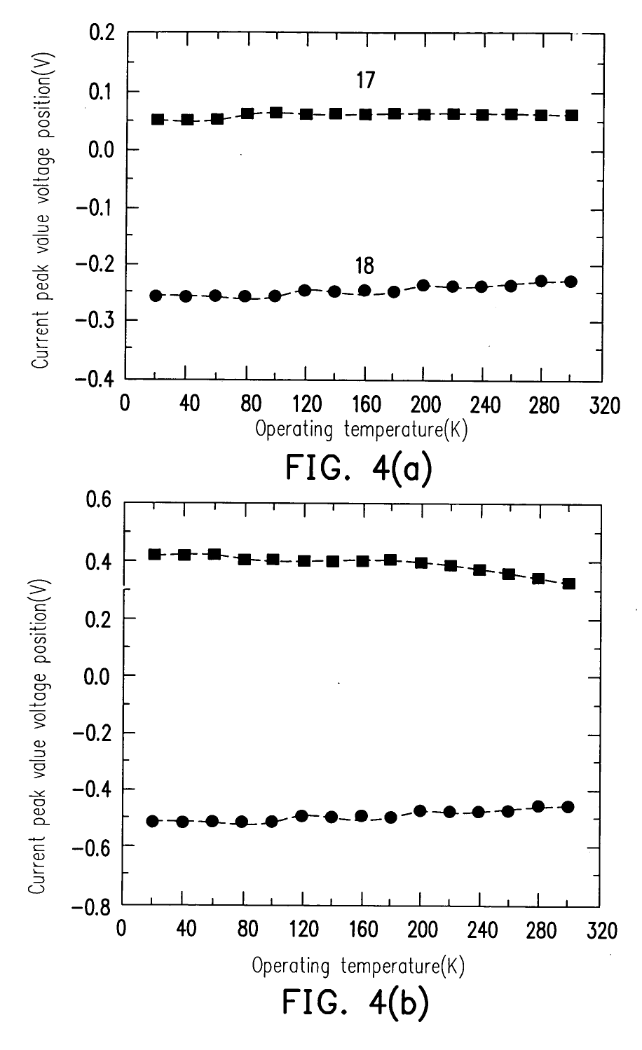

FIGS. 4(a) and 4(b) schematically show the curve diagrams illustrating the variance of the current peak-to-valley value position to the temperature of the device provided by the present invention under the positive and negative biases, respectively. It is observed from the diagrams that the temperature drift under the negative bias is about 0.107 mV/K, and the temperature drift under the positive bias is even lowered to 0.036 mV/K. In addition, the drift on the voltage position of the current valley value versus temperature is 0.393 mV/K.

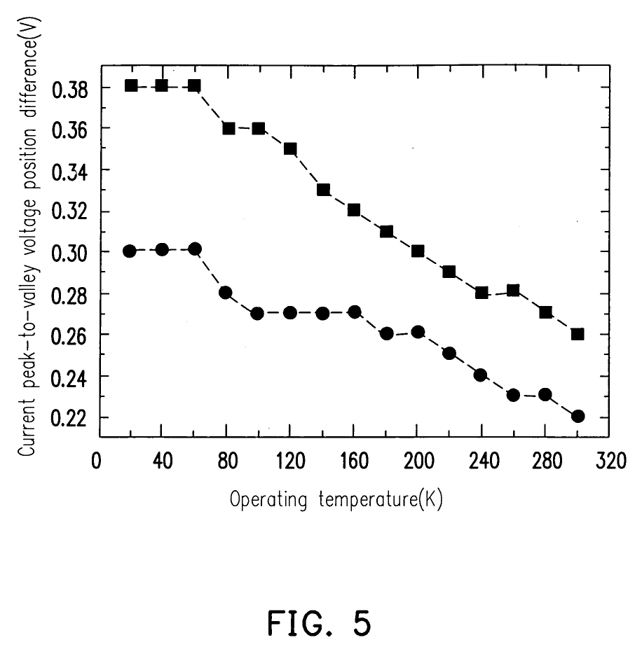

FIG. 5 is a schematic diagram showing the voltage relative position difference of the current peak-to-valley value to the temperature changes of the device provided by the present invention under the positive and negative biases. As shown in FIG. 5, the voltage relative position difference of the current peak-to-valley value to the temperature changes under the positive and negative bias is only 0.429 and 0.286 mV/K, respectively.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A resonant-tunneling quantum-dot device apparatus, comprising:
a semiconductor substrate;
a bottom semiconductor electron injection layer, disposed on the semiconductor substrate;
a bottom semiconductor barrier layer, defined by a periodic double-barrier disposed on the bottom semiconductor electron injection layer;
a periodic bottom semiconductor spacer layer, disposed on the bottom semiconductor barrier layer defined by the periodic double-barrier;
a periodic quantum-dot array layer, disposed on the periodic semiconductor spacer layer;
a periodic top semiconductor spatial layer, disposed on the periodic quantum-dot array layer;
a top semiconductor barrier layer, defined by the periodic double-barrier disposed on the periodic top semiconductor spatial layer; and
a top semiconductor electron injection layer, disposed on the top semiconductor barrier layer defined by the periodic double-barrier.

2. The resonant-tunneling semiconductor device of claim 1, wherein the semiconductor substrate is made of GaAs, InP, Al₂O₃, Si, or SiC, and the semiconductor substrate may be a semi-insulated or an N-doped layer.

3. The resonant-tunneling semiconductor device of claim 1, wherein the bottom semiconductor electron injection layer is an N-doped layer, the doping density thereof is about 1E18˜5E19 atoms/cm³, the thickness thereof is about 100˜1000 nm, and the growth temperature thereof is about 580˜610° C.

4. The resonant-tunneling semiconductor device of claim 1, wherein the bottom semiconductor barrier layer defined by the periodic double-barrier is a un-doped layer, the period number thereof is 2˜30, the thickness thereof is about 1˜5 nm, and the growth temperature thereof is about 470-530° C.

5. The resonant-tunneling semiconductor device of claim 1, wherein the periodic bottom semiconductor spatial layer is a un-doped layer, the period number thereof is 2-30, the thickness thereof is about 5-15 nm, and the growth temperature thereof is about 470-530° C.

6. The resonant-tunneling semiconductor device of claim 1, wherein the periodic quantum-dot array layer is an N-doped layer, the doping density thereof is about 1E17˜5E18 atoms/cm³, the period number thereof is 2˜30, the average thickness thereof is about 1.8˜3mL, and the growth temperature thereof is about 470˜530° C.

7. The resonant-tunneling semiconductor device of claim 1, wherein the periodic top semiconductor spacer layer is a un-doped layer, the period number thereof is 2˜30, the thickness thereof is about 5˜15 nm, and the growth temperature thereof is about 470˜530° C.

8. The resonant-tunneling semiconductor device of claim 1, wherein the top semiconductor barrier layer restricted by the periodic double-barrier is a un-doped layer, the period number thereof is 2˜30, the thickness thereof is about 1˜5 nm, and the growth temperature thereof is about 470˜530° C.

9. The resonant-tunneling semiconductor device of claim 1, wherein the top semiconductor electron injection layer is an N-doped layer, the doping density thereof is about 1E18˜5E19 atoms/cm³, the thickness thereof is about 100˜1000 nm, and the growth temperature thereof is about 580˜610° C.
